(19) United States
(12) Patent Application Publication
(10) Pub. No.: US 2019/0202945 A1
(43) Pub. Date: Jul. 4, 2019

(54) Hermetically-Sealed, Flexible Polymer Gel Cylinder for NMR Measurements

(71) Applicant: Alignment Technologies Company, Pittsburgh, PA (US)

(72) Inventor: Leandro Gil-Silva, Pittsburgh, PA (US)

(21) Appl. No.: 16/238,179

(22) Filed: Jan. 2, 2019

Related U.S. Application Data
(60) Provisional application No. 62/612,981, filed on Jan. 2, 2018.

(51) Int. Cl. C08F 2/06; C08F 2/01; C08F 6/12; C08F 6/10; B65D 81/20; G01R 33/28; G01R 33/46

(52) U.S. Cl. CPC C08F 2/06; C08F 2/01; C08F 6/12; C08F 20/18; B65D 81/2084; G01R 33/28; G01R 33/46; C08F 6/10

(57) ABSTRACT

A hermetically-sealed, flexible polymer gel cylinder comprising: a flexible polymer gel cylinder having a diameter, D_{dry}, and comprising a solvent that enhances the plasticity of the polymer gel cylinder compared an otherwise identical polymer gel cylinder with essentially no solvent, wherein the solvent is at an amount such that the flexible polymer gel, after being removed from the package and saturated with the solvent, has a swelled diameter, D_{swell}, and wherein D_{dry}≤D_{swell}≤5D_{dry}; and a package hermitically sealing the flexible polymer gel cylinder.

### CROSS-REFERENCE TO RELATED APPLICATIONS

This application is a U.S. non-provisional application claiming the benefit of U.S. Provisional Application No. 62/612,981, filed Jan. 2, 2018, which is incorporated herein by reference in its entirety.

### FIELD OF THE INVENTION

The present invention generally pertains to the field of nuclear magnetic resonance (NMR) spectroscopy. More particularly, the present invention pertains to an alignment material that may be used for NMR spectroscopy.

### BACKGROUND OF INVENTION

Conventional polymeric alignment materials for conducting NMR spectroscopy and the methods of making the same such as disclosed by Horst et al. (EP 1 512 984) and Gayathri et al., Residual Dipolar Couplings (RDCs) Analysis of Small Molecules Made Easy: Fast and Tuneable Alignment by Reversible Compression/Relaxation of Reusable PMMA Gels, Chem. Eur. J. 2010, 16, 3622-3626 suffer from a lack of consistency or reproducibility. In fact, the lack of consistency is so great that a spectroscopist is essentially gambling every time he or she dissolves an analyte into the alignment material using a solvent that the polymeric material will break or crack upon being swollen. Thus, a need still exists for polymeric alignment materials that have good reproducibility when used by persons conducting NMR spectroscopy on analytes introduced into the alignment material.

### SUMMARY OF INVENTION

In one embodiment, the present invention is directed to a method of preparing a hermetically-sealed, flexible polymer gel cylinder suitable for use as an alignment medium to measure residual dipolar couplings of an analyte via nuclear magnetic resonance spectroscopy, the method comprising:
hermetically sealing a flexible polymer gel cylinder having a diameter, D_{dry}, in a package thereby forming the hermetically-sealed, flexible polymer gel; wherein the flexible polymer gel cylinder comprises a solvent that enhances the plasticity of the polymer gel cylinder compared an otherwise identical polymer gel cylinder with essentially no solvent, and the solvent is at an amount such that the flexible polymer gel, after being removed from the package and saturated with the solvent, has a swelled diameter, D_{swell}, and wherein D_{dry}≤D_{swell}≤5·D_{dry}.

In another embodiment, the present invention is directed to a hermetically-sealed, flexible polymer gel cylinder suitable for use as an alignment medium to measure phenomena arising from anisotropic nuclear magnetic resonance spectroscopy of an analyte, the hermetically-sealed, flexible polymer gel cylinder comprising:
a flexible polymer gel cylinder having a diameter, D_{dry}, and comprising a solvent that enhances the plasticity of the polymer gel cylinder compared an otherwise identical polymer gel cylinder with essentially no solvent, wherein the solvent is at an amount such that the flexible polymer gel, after being removed from the package and saturated with the solvent, has a swelled diameter, D_{swell}, and wherein D_{dry}≤D_{swell}≤5·D_{dry}; and
a package hermitically sealing the flexible polymer gel cylinder.

In yet another embodiment, the present invention is directed to a method of preparing a hermetically-sealed, flexible polymer gel cylinder suitable for use as an alignment medium to measure phenomena arising from anisotropic nuclear magnetic resonance spectroscopy of an analyte, the method comprising:

(a) synthesizing a polymer gel cylinder having a synthesized diameter, D_{syn}, by a process comprising polymerizing a monomer solution that comprises one or more monomers that make up the polymer and a synthesis solvent, wherein the synthesized polymer gel cylinder comprises cross-linked polymer chains, the synthesis solvent, unreacted solute(s) of the monomer solution, and impurities;

(b) washing of the synthesized polymer gel cylinder with an extraction solvent to extract unreacted solute(s) of the monomer solution and/or impurities from the synthesized polymer gel to form a washed polymer gel cylinder, wherein the washed polymer gel cylinder comprises cross-linked polymer chains and extraction solvent, and wherein the washed polymer gel cylinder has a washed diameter, D_{wash}, and wherein D_{syn}<D_{wash};

(c) evaporating a portion of the extraction solvent from the washed polymer gel cylinder to form a partially-dried polymer gel cylinder having a partially-dried diameter, D_{dry}, wherein D_{syn}<D_{dry}<D_{wash}; and

(d) hermetically sealing the partially-dried polymer gel cylinder in a package thereby forming the hermetically-sealed, flexible polymer gel cylinder;

wherein the flexible polymer gel cylinder, after being removed from the package and saturated with a swelling solvent, has a swelled diameter, D_{swell}, and wherein D_{dry}≤D_{swell}≤5·D_{dry}.

In still another embodiment, the present invention is directed to a hermetically-sealed flexible polymer gel cylinder made by a method comprising:

(a) synthesizing a polymer gel cylinder having a synthesized diameter, D_{syn}, by a process comprising polymerizing a monomer solution that comprises one or more monomers that make up the polymer and a synthesis solvent, wherein the synthesized polymer gel cylinder comprises cross-linked polymer chains, the synthesis solvent, unreacted solute(s) of the monomer solution, and impurities;

(b) washing of the synthesized polymer gel cylinder with an extraction solvent to extract unreacted solute(s) of the monomer solution and/or impurities from the synthesized polymer gel to form a washed polymer gel cylinder, wherein the washed polymer gel cylinder comprises cross-linked polymer chains and extraction solvent, and wherein the washed polymer gel cylinder has a washed diameter, D_{wash}, and wherein D_{syn}<D_{wash};

(c) evaporating a portion of the extraction solvent from the washed polymer gel cylinder to form a partially-dried polymer gel cylinder having a partially-dried diameter, D_{dry}, wherein D_{syn}<D_{dry}<D_{wash}; and

(d) hermetically sealing the partially-dried polymer gel cylinder in a package thereby forming the hermetically-sealed, flexible polymer gel cylinder; wherein the flexible polymer gel cylinder, after being removed from the package and saturated with a swelling solvent, has a swelled diameter, D_{swell}, and wherein D_{dry}≤D_{swell}≤5·D_{dry}.

### DETAILED DESCRIPTION OF INVENTION

It was discovered that the reproducibility of polymeric alignment material may be improved by enhancing the plasticity of the material. Further, it was discovered that the plasticity may be enhanced by implementing one or more changes in the manufacturing process. One such change is to synthesize the polymer with monomer(s) in solution (i.e., via solution polymerization) rather than by bulk polymerization. It is believed that the lack of solvent in bulk polymerization significantly contributes to a brittle polymer that is prone to cracking. Although this may not necessarily true for all polymers, it has been a problem with acrylate polymers commonly used as alignment media. In contrast, it is believed the presence of solvent during solution polymerization significantly enhances the plasticity of the synthesized polymer compared to an identical polymer formed via bulk polymerization.

It also bears mentioning the polymer gel cylinder prepared via bulk polymerization as disclosed by Horst et al. involves first synthesizing an uncrosslinked polymer and uncrosslinked polymer is subsequently crosslinked using heat or radiation. Whereas, the solvent polymerization process disclosed and used herein may be performed such that polymer chain formation and cross-linking occur in the same step or essentially simultaneously, which simplifies the manufacturing process.

In one embodiment, a polymer gel cylinder of the present invention may be used as a tension- or stretching-type alignment medium as disclosed by Horst et al. In another embodiment, a polymer gel cylinder of the present invention may be used as a compression-type alignment medium as disclosed by Gayathri et al. It is believed that the compression-type alignment media advantageously provide much more variability in achieving different degrees of alignment and repeatability in achieving a particular degree of alignment because the degree of alignment is directly correlated to the degree of compression, which is readily controlled in this arrangement. In contrast, for tension- or stretching-type alignment media, the degree of stretching and hence the degree of alignment is essentially fixed.

As indicated above, in one embodiment, the method of preparing a hermetically-sealed, flexible polymer gel cylinder suitable for use as an alignment medium to measure phenomena arising from anisotropic nuclear magnetic resonance spectroscopy of an analyte comprises the general steps of: (a) synthesizing a polymer gel cylinder via solution polymerization; (b) washing the synthesized polymer gel cylinder with an extraction solvent; (c) partially drying the washed polymer gel cylinder; and (d) hermetically sealing the partially-dried polymer gel cylinder.

### A. Synthesis of the Polymer Gel Cylinder Via Solution Polymerization

The method includes synthesizing a polymer gel cylinder having a synthesized diameter, D_{syn}, by a process comprising polymerizing a monomer solution that comprises one or more monomers that form the polymer and a synthesis solvent, wherein the synthesized polymer gel cylinder comprises cross-linked polymer chains, the synthesis solvent, unreacted solute(s) of the monomer solution, and impurities.

Essentially any covalently crosslinked polymer having a crosslink density that is not too little nor too great may be used. Stated another way, the crosslink density must be great enough that it is not dissolved in NMR solvent but not so great as to not adequately swell when exposed to NMR solvent containing analyte. Examples of suitable polymers may be found in the Table entitled “Solvents and Non-solvents for Polymers” or the Polymer Handbook, Immergut et al., 1989. More specifically, suitable polymers may be selected from the group consisting of polyacrylam ides, polyacrylates, polydienes, polyacetylenes, polyalkenes, polyacrylic acids, polymethacrylates, polydisubstituted esters, polymethacrylam ides, vinyl-based polymers, polyesters, polystyrenes, polycarbonates, polyurethanes, poly anhydrides, polysulfonates, polysulfones, silicon containing polymers such as polysiloxanes and polysilanes, polyamides, and co-polymers thereof.

The cross-linking and bulk polymerization of the polymers is achieved using standard methods. Typically, a relatively small amount of a divalent or multifunctional monomer is included in the monomer solution with a monofunctional monomer mixture. While it is possible that the monofunctional monomer may be polymerized (chain formation) to produce an uncrosslinked polymer that is subsequently crosslinked by, for example, using an initiator capable of generating radicals, as indicated above, the present invention allows for chain formation and crosslinking to be accomplished simultaneously.

The polymerization may be carried out in any appropriate mechanism such as free radical polymerization or ionic polymerization. Free radical initiation may be accomplished by heating or radiating the monomer solution, which may comprises an initiator.

Though not always necessary, a broad range of initiators may be used to facilitate or aid polymerization. Exemplary initiators include peroxides such as benzoyl peroxide, hydroperoxides such as cumil hydroperoxide), azo compounds such as 2,2′-Azobis(4-methoxy-2,4-dimethylvaleronitrile), and photoinitiators such as benzoin. Exemplarily high energy radiation for cause free radical formation include alpha- and beta-particles, gamma-rays, x-rays, and plasma polymerization.

In one embodiment, the monomer solution comprises a monofunctional monomer and a multifunctional monomer, and an initiator suitable for initiating the polymerization reaction of the monofunctional monomer and multifunctional monomer.

Examples of polymers that may be produced via ionic polymerization include ionic polymerization include, for example, polyisobutylene, polybutenes, poly(vinyl ether), polycyanoacrylate, and polyisoprene. Cationic polymerization may be aided with the use of initiators such as H₂SO₄, H₃PO₄, AlCl₃, BF₃. In the case of anionic polymerization, alkali organometallic compounds can be used for initiation (e.g., n-butyl lithium). Vinyl polymerization may also may also be achieved through the use of complex coordination catalysts for a low energy synthesis of certain vinyl compounds such as polyethylene.

In one embodiment, the polymer of the polymer gel is selected from the group consisting of polyethylene, polyvinyl chloride, polychloropene, poly(methyl methacrylate), poly(hydroxyethyl methacrylate), polyvinyl acetate, polyacrylamide, polytetrafluoroethylene, polytrifluoroethane, polystyrene, and polyacrylonitrile.

Similarly, crosslinking may be accomplished by any appropriate mechanism for the polymers being formed. For example, crosslinking is accomplished through the including of a multifunctional monomer in the monomer solution. The multifunctional monomer is typically included at an amount of about 0.05 wt. % to about 2.0 wt. % based on the total weight of the monomers. Preferably, the functional groups of the multifunctional monomer match that of the monofunctional monomer (e.g., methyl methacrylate and ethylene glycol dimethacrylate). Crosslinking may also be accomplished with irradiation, reacting labile functional groups, and/or ionic cross-linking.

As indicated above, along with chain formation, the monomer(s) are cross-linked, which prevents dissolution of the polymer in the selected NMR solvent. Accordingly, the minimum degree of cross-linking is determined by the solvent's capability of dissolving the polymer. An increase in the degree of cross-linking tends to result in a tighter polymer network with stronger alignment properties. At a certain degree of cross-linking, however, the polymer will be incapable of swelling. Thus, there is an upper limit on the degree of cross-linking of the polymer for its use in NMR spectroscopy.

As mentioned, the polymer gel is typically in the shape of a cylinder to conduct NMR spectroscopy. While the polymer gel may be synthesized within a mold so that it has a cylindrical shape, that is not necessary. The polymer may be synthesized as a “blank” and then milled or shaped after polymerization. Alternatively, the polymer could she synthesized and shaped at the same time but without a mold such as by 3D printing.

### Washing the Synthesized Polymer Gel Cylinder

After the chain formation and cross-linking and preferably after being shaped if that is done separately, the synthesized polymer gel cylinders are washed with an extraction solvent to extract unreacted solute(s) of the monomer solution and/or impurities from the synthesized polymer gel to form a washed polymer gel cylinder, wherein the washed polymer gel cylinder comprises cross-linked polymer chains and extraction solvent, and wherein the washed polymer gel cylinder has a washed diameter, D_{wash}, and wherein D_{syn}<D_{wash}.

In an embodiment, the washing is conducted at an elevated temperature. Increasing the temperature of the washing tends to increase the rate at which unreacted solutes of the monomer solution and/or impurities may be washed from the synthesized polymer gel. This may be achieved, for example, by heating the extraction solvent. In one such embodiment, the extraction solvent is at a temperature, T_{wash}, in a range of about 20° C. to about the boiling point of the washing solvent. To date, it has been observed that having T_{wash} be no more than 10° C. less than the boiling point of the washing solvent is particularly advantageous.

The washing is typically conducted until at least a minimum amount of unreacted solutions of the monomer solutions and/or impurities are removed. While this can vary depending upon the desired accuracy of the NMR spectroscopy, it is typical for the washing to be conducted for a duration, t_{wash}, sufficient to remove at least 99% of the unreacted solute(s) of the monomer solution and/or impurities.

The washing may be conducted at or below room temperature (e.g., simply soaking the polymer gel cylinders in extraction solvent while in a refrigerator). That said, it has been observed that the a desired degree of removal of unreacted solute(s) and impurities may usually be achieved more quickly by conducting the washing at a temperature that is greater than room temperature.

One particular manner of conducting the washing at an elevated temperature is to use a Soxhlet extractor, wherein the boiling flask of the Soxhlet extractor is heated to a temperature sufficient to vaporize the extraction solvent but not sufficient to vaporize the unreacted solute(s) of the monomer solution and impurities washed from the synthesized polymer gel. Specifically, one or more polymer gel cylinders are placed inside the extraction chamber of the Soxhlet extractor and evaporated solvent condenses and enters the extraction chamber at a temperature not too much below the boiling point of the solvent (e.g., within 10° C. less than the boiling point) and diffuses into the polymer gel cylinder(s) before being extracted from the gel cylinders, which removes unreacted solute(s) of the monomer solution and impurities. The washing may be accomplished with a number of cycles in the Soxhlet extractor, depending upon the amount of unreacted solute(s) of the monomer solution and impurities. The number of cycles necessary to reach a desire degree of purities is readily ascertained by NMR.

Advantageously, it has been observed that conducting the washing at an elevated temperature increases the plasticity of the polymer gel cylinders beyond that which would be observed simply by the increased amount of solvent within the gel cylinders. This temperature-based increase in plasticity may be referred to herein as “annealing” and the resulting washed polymer gel cylinder as being “annealed.” Thus, in one embodiment, the T_{wash} and the t_{wash} are such that the washed polymer gel cylinder has a greater plasticity than the synthesized polymer gel cylinder. It is believed that this enhanced plasticity or flexibility may be particularly advantageous for polymer gel cylinders that are to be used as a stretched or tension alignment media.

### Partially Drying the Washing Polymer Gel Cylinder

The washed polymer gel cylinder is partially dried by evaporating a portion of the extraction solvent from the washed polymer gel cylinder to form a partially-dried polymer gel cylinder having a partially-dried diameter, D_{dry}, wherein D_{syn}<D_{dry}<D_{wash}. In other words, although the diameter of the partially-dried polymer gel cylinder will be less than when it was just washed, there will be more solvent in than just have the synthesis of the polymer.

This partial or controlled drying is counter to conventional thought regarding alignment media formed via bulk polymerization, which produces a completely dry polymer gel cylinder. It is largely believed that a dry polymer gel cylinder is better because it will readily absorb NMR solvent containing analyte. That said, it has been observed that a partially-dried polymer gel cylinder will adequately absorb NMR solvent containing analyte.

In one embodiment, the evaporating comprises indirectly heating the washed polymer gel cylinder in a sealed atmosphere such that the partially-dried polymer gel cylinder is at a drying temperature, T_{dry}, in a range of about 0° C. to about 120° C. for a drying duration, t_{dry}, in a range of about 15 minutes to about 30 days. Advantageously, the sealed atmosphere is believed to ensure an even drying of the polymer gel cylinder.

In one embodiment, the drying may be accomplished by placing one or more polymer gel cylinders in a beaker on a surface elevated from the base of the beaker and a watch glass is placed on top to seal the interior of the beaker. The beaker is then placed on a hot plate. By elevating the polymer gel cylinders, they are not in direct contact with the heater surface of the beaker. This indirect heat is also believe to aid in even drying of the polymer gel cylinders. The drying is conducted to leave an amount of solvent in the polymer gel cylinders that is enough to ensure adequate plasticity and flexibility but not so much as to prevent enough swelling to function as alignment media for NMR spectroscopy.

### Co-Analyte

In one embodiment, the partially-dried polymer gel cylinder may also comprise a co-analyte, which may be introduced with the washing solvent, or after washing but before drying, or even after being partially dried. The polymer gel cylinder comprising the co-analyte may be used to create standards for quantitative NMR or fragment libraries. Alternatively, polymer gel cylinders with co-analytes may be used to determine chirality via anisotropic NMR by having chiral co-analytes that form dimers with stereoisomers.

### Hermetically Sealing the Partially-dried Polymer Gel Cylinder

The partially-dried polymer gel cylinder is hermetically sealed in a package thereby resulting the hermetically-sealed, flexible polymer gel cylinder. Hermetically sealing the polymer gel cylinder maintains its flexibility so that is much less likely to break while being swollen. As indicated above, although it is only partially-dried, it is still able to adequately swell when exposed to an NMR swelling solvent containing analyte. For example, it may have a swelled diameter, D_{swell}, that is D_{dry}≤D_{swell}≤5·D_{dry}.

### EXAMPLE

A solution of methyl methacrylate, ethylene glycol dimethacrylate, 2,2′-azobis(4-methoxy-2,4-dimethylvaleronitrile), and acetone was prepared. The solution was run through a column of aluminum oxide to remove inhibitor (monomethyl ether hydroquinone). Then, the solution was degassed using the freeze-pump-thaw cycle three times. Then, the degassed solution was injected into a rod-shaped mold with an interior diameter of about 2.7 mm and a length of about 14.5 cm. The mold, with the solution therein, was heated to about 47° C. for about 12 hours to polymerize the monomers.

After the polymerization, the cross-linked polymer rod was removed from the mold. The polymer rod was cut into cylinders of about 2.5 cm in length. The cylinders were placed inside an extraction chamber of a Soxhlet. The washing solvent, acetone, was placed into the boiling flask and brought to a rolling boil. Vaporized acetone was condensed into the extraction chamber until solvent level is the same as the siphon arm and condensed solvent is purged into the boiling flask. This cycle was repeated for about one hour. Then, the solvent in the boiling flask was replaced with clean solvent and the above-described cycle of washing was repeated two more times.

After completing the washing, the solvent-saturated polymer cylinders were placed in a container and subjected to a controlled desiccation or drying to evaporate a portion of the solvent in the cylinders. The container is designed and set up such that it creates a regulated atmosphere when it is heated. This is achieved by having a small perforation in the container, which maintained acetone vapor in the atmosphere of the container as the polymer cylinders a partially dried. The drying process decreased the length of the cylinders from about 3.4 cm to about 2.9 cm at which time the cylinders were hermetically sealed in glass ampules.

Having illustrated and described the principles of the present invention, it should be apparent to persons skilled in the art that the invention can be modified in arrangement and detail without departing from such principles.

Although the materials and methods of this invention have been described in terms of various embodiments and illustrative examples, it will be apparent to those of skill in the art that variations can be applied to the materials and methods described herein without departing from the concept, spirit and scope of the invention. All such similar substitutes and modifications apparent to those skilled in the art are deemed to be within the spirit, scope and concept of the invention as defined by the appended claims.

What is claimed is:

1. A method of preparing a hermetically-sealed, flexible polymer gel cylinder suitable for use as an alignment medium to measure residual dipolar couplings of an analyte via nuclear magnetic resonance spectroscopy, the method comprising:
hermetically sealing a flexible polymer gel cylinder having a diameter, D_{dry}, and comprising cross-linked polymer chains and solvent in a package thereby forming the hermetically-sealed, flexible polymer gel;
wherein the flexible polymer gel cylinder comprises a solvent that enhances the plasticity of the polymer gel cylinder compared an otherwise identical polymer gel cylinder with essentially no solvent, and the solvent is at an amount such that the flexible polymer gel, after being removed from the package and saturated with the solvent, has a swelled diameter, D_{swell}, and wherein D_{dry}<D_{swell}≤5·D_{dry}.

2. A hermetically-sealed, flexible polymer gel cylinder suitable for use as an alignment medium to measure phenomena arising from anisotropic nuclear magnetic resonance spectroscopy of an analyte, the hermetically-sealed, flexible polymer gel cylinder comprising:
a flexible polymer gel cylinder having a diameter, D_{dry}, and comprising cross-linked polymer chains and a solvent that enhances the plasticity of the polymer gel cylinder compared an otherwise identical polymer gel cylinder with essentially no solvent, wherein the solvent is at an amount such that the flexible polymer gel, after being removed from the package and saturated with the solvent, has a swelled diameter, D_{swell}, and wherein D_{dry}<D_{swell}≤5·D_{dry}; and
a package hermitically sealing the flexible polymer gel cylinder.

3. A method of preparing a hermetically-sealed, flexible polymer gel cylinder suitable for use as an alignment medium to measure phenomena arising from anisotropic nuclear magnetic resonance spectroscopy of an analyte, the method comprising:
(a) synthesizing a polymer gel cylinder having a synthesized diameter, D_{syn}, by a process comprising polymerizing a monomer solution that comprises one or more monomers that make up the polymer and a synthesis solvent, wherein the synthesized polymer gel cylinder comprises cross-linked polymer chains, the synthesis solvent, unreacted solute(s) of the monomer solution, and impurities;
(b) washing of the synthesized polymer gel cylinder with an extraction solvent to extract unreacted solute(s) of the monomer solution and/or impurities from the synthesized polymer gel to form a washed polymer gel cylinder, wherein the washed polymer gel cylinder comprises cross-linked polymer chains and extraction solvent, and wherein the washed polymer gel cylinder has a washed diameter, D_{wash}, and wherein D_{syn}<D_{wash};
(c) evaporating a portion of the extraction solvent from the washed polymer gel cylinder to form a partially-dried polymer gel cylinder having a partially-dried diameter, D_{dry}, wherein D_{syn}<D_{dry}<D_{wash}; and
(d) hermetically sealing the partially-dried polymer gel cylinder in a package thereby forming the hermetically-sealed, flexible polymer gel cylinder;
wherein the flexible polymer gel cylinder, after being removed from the package and saturated with a swelling solvent, has a swelled diameter, D_{swell}, and wherein D_{dry}≤D_{swell}<5·D_{dry}.

4. The method of claim 3, wherein:
the monomer of the monomer solution comprises a monofunctional monomer and a multifunctional monomer; and
the monomer solution further comprises an initiator suitable for initiating the polymerization reaction of the monofunctional monomer and multifunctional monomer.

5. The method of claim 3, wherein D_{dry}≤5·D_{syn}.

6. The method of claim 3, wherein the extraction solvent is at a temperature, T_{wash}, in a range of about 20° C. to about the boiling point of the washing solvent.

7. The method of claim 6, wherein T_{wash} is no more than 10° C. less than the boiling point of the washing solvent.

8. The method of claim 6, wherein the washing is conducted for a duration, t_{wash}, sufficient to remove at least 99% of the unreacted solute(s) of the monomer solution and/or impurities.

9. The method of claim 8, wherein the T_{wash} and the t_{wash} are such that the washed polymer gel cylinder has a greater plasticity than the synthesized polymer gel cylinder.

10. The method of claim 3, wherein the washing is conducted with a Soxhlet extractor, wherein the boiling flask of the Soxhlet extractor is heated to a temperature sufficient to vaporize the extraction solvent but not sufficient to vaporize the unreacted solute(s) of the monomer solution and impurities washed from the synthesized polymer gel.

11. The method of claim 3, wherein the evaporating comprises indirectly heating the washed polymer gel cylinder in a sealed atmosphere such that the partially-dried polymer gel cylinder is at a drying temperature, T_{dry}, in a range of about 0° C. to about 120° C. for a drying duration, t_{dry}, in a range of about 15 minutes to about 30 days.

12. The method of claim 3, wherein the polymer of the polymer gel is selected from the group consisting of polyethylene, polyvinyl chloride, polychloropene, poly(methyl methacrylate), poly(hydroxyethyl methacrylate), polyvinyl acetate, polyacrylamide, polytetrafluoroethylene, polytrifluoroethane, polystyrene, and polyacrylonitrile.

13. A hermetically-sealed, flexible polymer gel cylinder made by the method of claim 3.

14. The hermetically-sealed, flexible polymer gel cylinder of claim 13, wherein:
the monomer of the monomer solution comprises a monofunctional monomer and a multifunctional monomer;
the monomer solution further comprises an initiator suitable for initiating the polymerization reaction of the monofunctional monomer and multifunctional monomer;
D_{dry}≤5·D_{syn};
the extraction solvent is at a temperature, T_{wash}, in a range of about 20° C. to about 10° C. less than the boiling point of the washing solvent;
the washing is conducted for a duration, t_{wash}, sufficient to remove at least 99% of the unreacted solute(s) of the monomer solution and/or impurities; and
the T_{wash} and the t_{wash} are such that the washed polymer gel cylinder has a greater plasticity than the synthesized polymer gel cylinder.

15. The hermetically-sealed, flexible polymer gel cylinder of claim 14, wherein the washing is conducted with a Soxhlet extractor, wherein the boiling flask of the Soxhlet extractor is heated to a temperature sufficient to vaporize the extraction solvent but not sufficient to vaporize the unreacted solute(s) of the monomer solution and impurities washed from the synthesized polymer gel.

16. The hermetically-sealed, flexible polymer gel cylinder of claim 13, wherein the evaporating comprises indirectly heating the washed polymer gel cylinder in a sealed atmosphere such that the partially-dried polymer gel cylinder is at a drying temperature, T_{dry}, in a range of about 0° C. to about 120° C. for a drying duration, t_{dry}, in a range of about 15 minutes to about 30 days.

17. The hermetically-sealed, flexible polymer gel cylinder of claim 13, wherein the polymer of the polymer gel is selected from the group consisting of polyethylene, polyvinyl chloride, polychloropene, poly(methyl methacrylate), poly(hydroxyethyl methacrylate), polyvinyl acetate, polyacrylamide, polytetrafluoroethylene, polytrifluoroethane, polystyrene, and polyacrylonitrile.
